(19) United States
(12) Patent Application Publication
(10) Pub. No.: US 2010/0105212 A1
(43) Pub. Date: Apr. 29, 2010

(54) METHOD FOR FABRICATING SEMICONDUCTOR DEVICE

(76) Inventor: Chung-Kyung Jung, Anyang-si (KR)

Correspondence Address: SHERR & VAUGHN, PLLC, 620 HERNDON PARKWAY, SUITE 320, HERNDON, VA, 20170, US

(21) Appl. No.: 12/574,986

(22) Filed: Oct. 7, 2009

(30) Foreign Application Priority Data
Oct. 23, 2008 (KR) 10-2008-014156

(51) Int. Cl. H01L 21/3065

(52) U.S. Cl. 438/712; 257/E21.218

(57) ABSTRACT

A method of fabricating a device, including a semiconductor device. A method of fabricating a semiconductor device may include forming a photoresist pattern on and/or over a substrate, which may expose a predetermined region supposed to include a metal line thereover. A method of fabricating a semiconductor device may include etching a substrate, for example using reactive ion etching, which may use a photoresist pattern. A method of fabricating a semiconductor device may include cleaning a substrate using a liquid inorganic compound. An apparatus may include a photoresist pattern over a substrate, and may include a substrate etched by reactive ion etching using a photoresist pattern and/or cleaned using a liquid inorganic compound.

The present application claims priority under 35 U.S.C. 119 to Korean Patent Application No. 10-2008-0104156 (filed on Oct. 23, 2008) which is hereby incorporated by reference in its entirety.

### BACKGROUND

Embodiments relate to an electric device and methods thereof. Some embodiments relate to a semiconductor device and a method of fabricating a semiconductor device.

Aluminum (Al), aluminum alloy, tungsten (W) and like materials may be used to form a metal line of a semiconductor device. As the size of a semiconductor becomes relatively smaller, the pitch size of an aluminum line process tends to become relatively smaller. As semiconductor devices trend towards relatively smaller sizes, the size of an aluminum line has become relatively smaller.

According to Back-End-Of-Line (BEOL) processes, patterns may be formed using a photolithography process to form an aluminum line. An optimized process may need to be performed over regions having formed patterns during etching and/or cleaning processes which may not generate fine patterns and/or which may generate substantial polymer residues and/or line attack. Although the relative size of an aluminum line may be reduced during a BEOL process, polymer residues may be disposed in and/or over an aluminum surface and/or a side wall, which may relatively deteriorate product reliability and/or may relatively reduce product usage life.

Accordingly, there is a need for a method of manufacturing a device, such as a semiconductor device, which may establish an optimized process substantially without polymer residue and/or line attack, and/or which may maximize characteristics of a device.

### SUMMARY

Embodiments relate to a method of fabricating a device. Some embodiments relate to a method of fabricating a semiconductor device. According to embodiments, a method of fabricating a semiconductor device may maximize characteristics of a device. In embodiments, an optimized process may be established substantially without polymer residue and/or line attack.

According to embodiments, a method of fabricating a semiconductor device may include forming a photoresist pattern on and/or over a substrate. In embodiments, a photoresist pattern may expose a predetermined region supposed to include a metal line thereover. In embodiments, a method of fabricating a semiconductor device may include etching a substrate, for example using reactive ion etching (RIE), which may use a photoresist pattern. In embodiments, a method of fabricating a semiconductor device may include cleaning a substrate using a liquid inorganic compound.

According to embodiments, a method of fabricating a semiconductor device may maximize characteristics of a semiconductor device. In embodiments, a method of fabricating a semiconductor device may maximize etching and/or cleaning processes. In embodiments, eco-friendly chemicals may be used.

### DRAWINGS

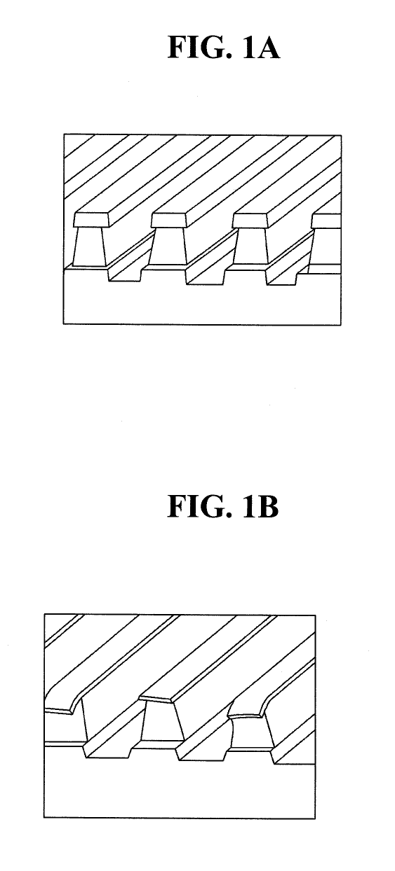

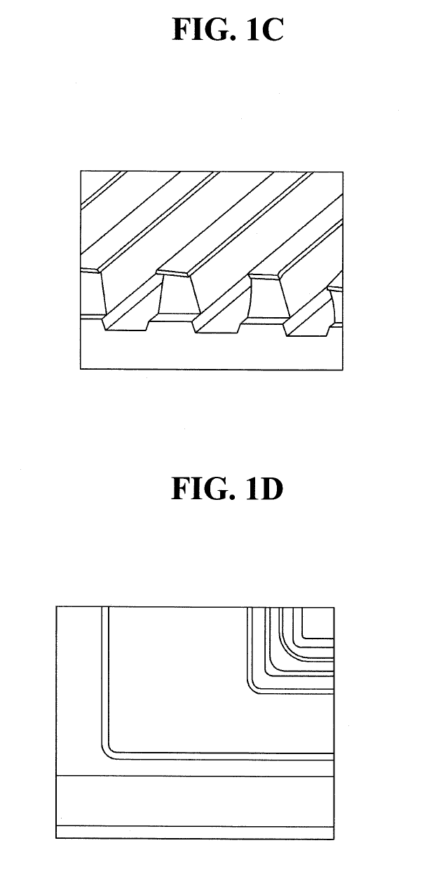

Example FIG. 1A to FIG. 1D illustrate pattern shapes with respect to changes in source power after a cleaning process and a cleaning process time period in accordance with embodiments.

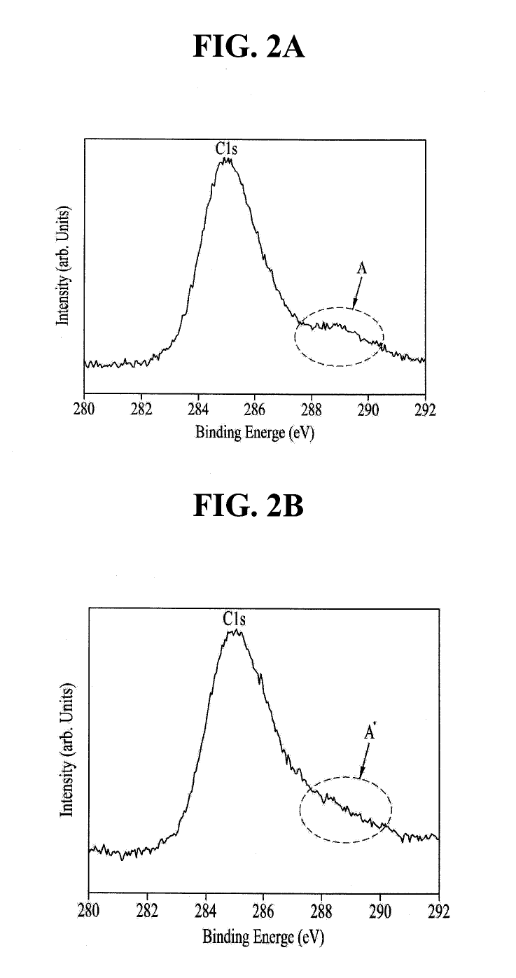

Example FIG. 2A illustrates XPS data for a method of fabricating a semiconductor device.

Example FIG. 2B illustrates XPS data for a method of fabricating a semiconductor device in accordance with embodiments

### DESCRIPTION

Some embodiments relate to a method of fabricating a semiconductor device. According to embodiments, a method of manufacturing a semiconductor device may provide an optimized process substantially without polymer residue and/or line attack, and/or may maximize characteristics of a device. Referring to example Table 1, example conditions are listed for etching and/or cleaning processes which may relate to a method of fabricating a semiconductor device in accordance with embodiments.

TABLE 1

| | | | Bias | | Post- |
|---|---|---|---|---|---|
| | Cl2(Sccm) | CHF3(Sccm) | Power | Ws Power | ash(LIC-3) |
| T1 | 60 | 6 | 80 | 700 W | 55 sec |
| T2 | 60 | 6 | 80 | 800 W | 55 sec |
| T3 | 60 | 6 | 80 | 1000 W | 55 sec |
| T4 | 60 | 6 | 80 | 800 W | 45 sec |

According to embodiments, a method of fabricating a semiconductor device may include forming a pattern in a photolithography process used to form, for example, an aluminum line in a BEOL process. In embodiments, RIE etching may be performed when etching and/or cleaning processes are performed. In embodiments, RIE etching may be performed using RF plasma. In embodiments, cleaning may be performed using liquid inorganic compounds such as HF, H₂SO₄ and/or H₂O₂, which may reference a low temperature inorganic chemical (LIC-3). In embodiments, for example in Table 1, C₁₂ and CHF₃ may be used for etching at approximately 60 sccm and 6 sccm, respectively. In embodiments, bias power may be used at approximately 80 W. Ws power, which may relate to source power, may be adjusted to perform RIE etching in accordance with embodiments.

Referring to example FIG. 1A to FIG. 1D, pattern shapes are illustrated with respect to changes of source power after a cleaning process and a cleaning process time period in accordance with embodiments. According to embodiments, a cleaning process may be performed for approximately 55 seconds at approximately 700 W of Ws power (e.g., T1), and shapes of polymer residues may be found as illustrated in FIG. 1A. In embodiments, a cleaning process may be performed for approximately 55 seconds at approximately 800 W of Ws power (e.g., T2), and polymer residue or photoresist (PR) residue may not found on and/or over a pattern as illustrated in FIG. 1B. In embodiments, a cleaning process may be performed for approximately 55 seconds at approximately 100 W of Ws power (e.g., T3), and polymer residue or remaining PR may not found on and/or over a pattern as illustrated in FIG. 1C. Critical dimension (CD) may increase, which may deteriorate yield and/or reliability. In embodiments, a cleaning process may be performed for approximately 45 seconds at approximately 800 W of Ws power (e.g., T4), and polymer residue or remaining PR may be removed from a pattern to provide a relatively clean pattern surface substantially without any influence on line attack and/or CD.

According to embodiments, surface element analysis may be accomplished after an RIE etching and cleaning processes by X-ray photoelectron spectroscopy (XPS). Referring to example FIG. 2A, XPS data is illustrated for a method of fabricating a semiconductor device. Referring to example FIG. 2B, XPS data is illustrated for a method of fabricating a semiconductor device in accordance with embodiments.

Referring to FIG. 2A, polymer residue may be identified by the generation of carbon peak (A). In contrast, referring to FIG. 2B, a substantially less carbon peak (A') may be identified, which may indicate that polymer residue may be substantially completely removed. According to embodiments, a process condition for minimizing polymer residue in etching and/or cleaning processes may be obtained.

While solvents may be used as cleaning solutions for an aluminum line on and/or over a substrate having etching performed thereover, the chemical solutions may have a relatively high unit price and may be relatively harmful to environments. According to embodiments, LIC-3 which may reference a liquid inorganic compound (e.g., HF, H₂SO₄ and/or H₂O₂) may relatively reduce a process time period. In embodiments, LIC-3 may be relatively more eco-friendly than for example a solvent. In embodiments, LIC-3 may have a relatively smaller unit price. In embodiments, polymer residue on and/or over an aluminum line and/or line attack may be minimized more efficiently.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method for fabricating a semiconductor comprising steps of:
forming a photoresist pattern on a substrate to expose a predetermined region supposed to have a metal line formed thereon;
etching the substrate in RIE etching that uses the photoresist pattern; and
cleaning the substrate by using liquid inorganic compound.

2. The method of claim 1, wherein the liquid inorganic compound is LIC-3 (Low Temperature Inorganic Chemical).

3. The method of claim 2, wherein the LIC-3 is compound mixed with HF, H₂SO₄ and H₂O₂.

4. The method of claim 1, wherein the RIE etching is performed, with 60 sccm of C12, 6 sccm of CHF3 and 80 W of bias power.

5. The method of claim 1, wherein the RIE etching is performed with 800 W of source power.

6. The method of claim 1, wherein the cleaning process is performed for 45 seconds.
